(19) United States
(12) Patent Application Publication
(10) Pub. No.: US 2019/0123055 A1
(43) Pub. Date: Apr. 25, 2019

(54) SEMICONDUCTOR MEMORY DEVICE AND METHOD FOR MANUFACTURING SAME

(71) Applicant: TOSHIBA MEMORY CORPORATION, Minato-ku (JP)

(72) Inventor: Akira Matsumura, Yokkaichi (JP)

(73) Assignee: TOSHIBA MEMORY CORPORATION, Minato-ku (JP)

(21) Appl. No.: 16/131,735

(22) Filed: Sep. 14, 2018

(30) Foreign Application Priority Data
Oct. 20, 2017 (JP) 2017-203535

(51) Int. Cl. H01L 27/1157; H01L 27/11582

(52) U.S. Cl. CPC H01L 27/1157; H01L 27/11582

(57) ABSTRACT

A semiconductor memory device includes a substrate, a stacked body and a columnar part. The stacked body is provided above the substrate, and the columnar part is provided inside the stacked body. The stacked body includes a first stacked body including first electrode layers stacked in a first direction, and the second stacked body including second electrode layers stacked in the first direction, and a third electrode layer between the first stacked body and the second stacked body. The columnar part includes a first columnar part inside the first stacked body, a second columnar part inside the second stacked body, and a linking portion between the first and second columnar parts. The linking portion includes a first portion having a first thickness in a second direction crossing the first direction. The first thickness is wider than a thickness in the second direction of other portion in the linking portion.

### CROSS-REFERENCE TO RELATED APPLICATIONS

This application is based upon and claims the benefit of priority from Japanese Patent Application No. 2017-203535, filed on Oct. 20, 2017; the entire contents of which are incorporated herein by reference.

### FIELD

Embodiments relate to a semiconductor memory device and a method for manufacturing the same.

### BACKGROUND

A semiconductor memory device has been proposed in which memory cells are arranged three-dimensionally. In such a semiconductor memory device, a stacked body that includes multiple electrode layers is formed on a substrate; and a channel and a charge storage film are formed inside a memory hole extending through the stacked body. When the number of electrode layers stacked in the stacked body increases, multiple stacked bodies each including the smaller number of electrode layers and memory holes extending therethrough are build up sequentially. However, it becomes difficult to form the channel and the charge storage film in the memory holes connected through the multiple stacked bodies.

### BRIEF DESCRIPTION OF THE DRAWINGS

FIG. 1 is a cross-sectional view showing a semiconductor memory device according to a first embodiment;

FIGS. 2 to 13 are cross-sectional views showing a manufacturing method of the semiconductor memory device according to the first embodiment;

FIG. 14A is a cross-sectional view showing a portion of a semiconductor memory device according to a reference example;

FIG. 14B is a cross-sectional view showing a portion of the semiconductor memory device according to the first embodiment;

FIG. 15 is a cross-sectional view showing a semiconductor memory device according to a variation of the first embodiment; and

FIG. 16 is a cross-sectional view showing a semiconductor memory device according to a second embodiment.

### DETAILED DESCRIPTION

According to one embodiment, a semiconductor memory device includes a substrate, a stacked body and a columnar part. The stacked body is provided above the substrate, the stacked body including a plurality of electrode layers stacked to be separated from each other, the plurality of electrode layers being stacked in a first direction. The columnar part is provided inside the stacked body. The columnar part includes a semiconductor part and a memory film, the semiconductor part extending in the first direction, the memory film being provided between the stacked body and the semiconductor part. The plurality of electrode layers include a plurality of first electrode layers, a plurality of second electrode layers, and a third electrode layer provided between the plurality of first electrode layers and the plurality of second electrode layers. The stacked body includes a first stacked body and a second stacked body, the first stacked body including the plurality of first electrode layers and being positioned on the substrate side, the second stacked body including the plurality of second electrode layers, the third electrode layer being positioned between the first stacked body and the second stacked body. The columnar part including a first columnar part, a second columnar part, and a linking portion, the first columnar part being provided inside the first stacked body, the second columnar part being provided inside the second stacked body, the linking portion being provided between the first columnar part and the second columnar part. The linking portion includes a first portion, the first portion having a first thickness in a second direction crossing the first direction, the first thickness being wider than a thickness in the second direction of other portion in the linking portion, the first portion including a portion positioned in the first direction between an upper surface and a lower surface of the third electrode layer.

Hereinbelow, embodiments of the invention are described with reference to the drawings. It should be noted that the drawings are schematically or conceptually illustrated, and the relationship between dimensions such as a width and a thickness of each component illustrated and the ratio thereof are not necessarily the same as the actual ones. Moreover, the common component may be illustrated in the drawings with dimensions and ratios different from each other.

It should be also noted in the specification and the drawings that the common components referred to in the previous drawing are denoted with the same symbols, and not precisely described or omitted appropriately.

### First Embodiment

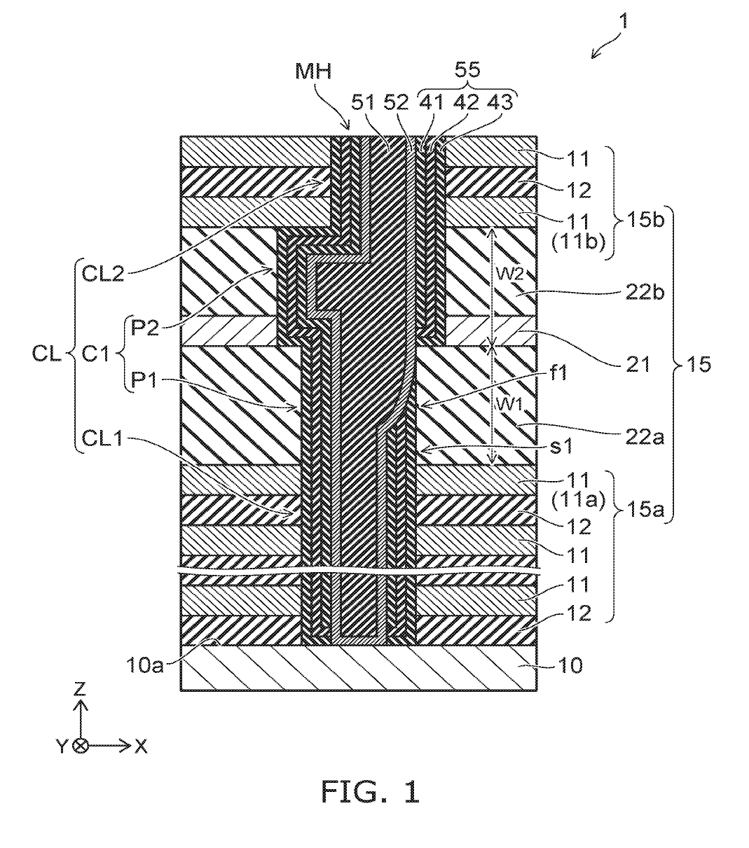

FIG. 1 is a cross-sectional view showing a semiconductor memory device 1.

As shown in FIG. 1, a substrate 10 is provided in the semiconductor memory device 1. The substrate 10 is a semiconductor substrate and includes silicon (Si) such as single-crystal silicon, etc.

In the specification, two mutually-orthogonal directions parallel to an upper surface 10a of the substrate 10 are taken as an X-direction and a Y-direction. A direction that is orthogonal to both the X-direction and the Y-direction is taken as a Z-direction.

A stacked body 15 and a columnar part CL are further provided in the semiconductor memory device 1. The stacked body 15 includes a first stacked body 15a, an insulating layer 22a, an electrode layer 21, an insulating layer 22b, and a second stacked body 15b.

The first stacked body 15a is provided on the substrate 10. The first stacked body 15a includes multiple electrode layers 11 and multiple insulating layers 12. The number of stacks of the electrode layers 11 in the first stacked body 15a is arbitrary.

For example, the multiple electrode layers 11 of the first stacked body 15a include a source-side select gate and word lines. For example, the source-side select gate corresponds to the electrode layer 11 of the lowermost layer among the multiple electrode layers 11 of the first stacked body 15a; and the word lines correspond to the electrode layers 11 other than the electrode layer 11 of the lowermost layer. For example, an electrode layer 11a of the uppermost layer among the multiple electrode layers 11 of the first stacked body 15a may be a dummy electrode layer.

Here, a dummy electrode layer is an electrode layer that is not selected in a read operation or a program operation and corresponds to an electrode layer to which a programming voltage or a read voltage for a memory cell is not supplied. The dummy electrode layer functions as a control gate of a transistor (a dummy cell), which surrounding a channel 52 with a charge storage film 42 interposed. However, the data programming is not performed for the charge storage film 42 of the dummy cell; and the dummy cell does not function as a memory cell in which data is programmed and retained.

When programming data, the dummy electrode layer holds, for example, at a potential same as the potential of the electrode layers 11 of unselected memory cells that are not to be programmed, and thus, data is not programmed to the dummy cell. Also, when reading data, the dummy electrode layer holds at a potential same as the potential of the electrode layers 11 of unselected memory cells from which data is not to be read out, and thus, data is not read out from the dummy cell.

An electrode layer 11 that is not the dummy electrode layer corresponds to the electrode layer 11 capable of being selected in the read operation and/or the program operation.

The electrode layers 11 each include a conductive material and include, for example, a metal such as tungsten (W), etc. A main portion that is made of, for example, tungsten and a barrier metal layer that is made from, for example, titanium nitride (TiN) and covers the surface of the main portion may be provided in each electrode layer 11.

The insulating layers 12 are provided on the substrate 10 and between the electrode layers 11. The insulating layers 12 include, for example, silicon oxide (SiO).

The insulating layer 22a is provided on the first stacked body 15a. For example, the insulating layer 22a includes the same material as the insulating layers 12, e.g., silicon oxide. For example, the thickness (a thickness W1) in the Z-direction of the insulating layer 22a is thicker than the thickness in the Z-direction of each of the insulating layers 12.

The electrode layer 21 is provided on the insulating layer 22a. The electrode layer 21 is a dummy electrode layer. For example, the electrode layer 21 includes the same material as the electrode layers 11, e.g., tungsten.

The insulating layer 22b is provided on the electrode layer 21. For example, the insulating layer 22b includes the same material as the insulating layers 12, e.g., silicon oxide. For example, the thickness in the Z-direction of the insulating layer 22b is thicker than the thickness in the Z-direction of each of the insulating layers 12.

The second stacked body 15b is provided on the insulating layer 22b. The second stacked body 15b includes the multiple electrode layers 11 and the multiple insulating layers 12. For example, the components of the second stacked body 15b are the same as the components of the first stacked body 15a. The electrode layers 11 and the insulating layers 12 are arranged alternately in the Z-direction in the second stacked body 15b. The number of stacks of the electrode layers 11 is arbitrary in the second stacked body 15b.

For example, the multiple electrode layers 11 of the second stacked body 15b include a drain-side select gate and word lines. For example, the drain-side select gate corresponds to the electrode layer 11 of the uppermost layer among the multiple electrode layers 11 of the second stacked body 15b; and the word lines correspond to the electrode layers 11 other than the electrode layer 11 of the uppermost layer. For example, an electrode layer 11b of the lowermost layer among the multiple electrode layers 11 of the second stacked body 15b may be a dummy electrode layer.

A memory hole MH (a through-hole) is provided in the stacked body 15. The columnar part CL is positioned inside the memory hole MH. In the case where the columnar part CL is multiply provided, for example, the multiple columnar parts CL are arranged in a lattice configuration in the X-direction and the Y-direction.

The columnar part CL includes a core insulating film 51, the channel 52, and a memory film 55. The memory film 55 includes a tunneling insulating film 41, the charge storage film 42, and a blocking insulating film 43.

The core insulating film 51 includes, for example, silicon oxide. For example, the core insulating film 51 extends in the Z-direction in a columnar configuration. The core insulating film 51 may not be included in the columnar part CL.

The channel 52 is provided at the periphery of the core insulating film 51. The channel 52 is a semiconductor part and includes, for example, silicon. The channel 52 includes, for example, polysilicon made of crystallized amorphous silicon. The channel 52 extends in the Z-direction in a tubular configuration. The lower end of the channel 52 is connected to the substrate 10 used as the source of the memory cell array.

A plug (not illustrated) that is formed of silicon or the like is provided at the upper end of the core insulating film 51. The periphery of the plug is surrounded with the channel 52; and the upper end of the plug is connected to a bit line (not illustrated) via a contact or the like.

The tunneling insulating film 41 is provided at the periphery of the channel 52. The tunneling insulating film 41 includes, for example, silicon oxide. Although the tunneling insulating film 41 includes a single-layer film such as a silicon oxide film or the like in the example shown in FIG. 1, the tunneling insulating film 41 may include multiple films. In the case where the tunneling insulating film 41 includes multiple films, a stacked film of a silicon oxide film and a silicon nitride film or a stacked film of a silicon oxide film and a silicon oxynitride film may be used for the tunneling insulating film 41.

The tunneling insulating film 41 provides a potential barrier between the charge storage film 42 and the channel 52. When programming, electrons pass through the tunneling insulating film 41 from the channel 52 into the charge storage film 42, and thereby, information is programmed in a memory cell. On the other hand, when erasing, holes pass through the tunneling insulating film 41 from the channel 52 into the charge storage film 42, and cancel the electron charges in the charge storage film 42. Thereby, the information stored in the memory cell is erased.

The charge storage film 42 is provided at the periphery of the tunneling insulating film 41. The charge storage film 42 includes, for example, silicon nitride (SiN).

The memory cell that includes the charge storage film 42 is formed at each crossing portion of the channel 52 and the electrode layers 11 (the word lines). The charge storage film 42 has trap sites that trap charges therein. The threshold voltage of the memory cell changes depending on the amount of the trapped charges or the trap site state such as the existence or absence of charge. Thereby, the memory cell stores information.

The blocking insulating film 43 is provided at the periphery of the charge storage film 42. The blocking insulating film 43 includes, for example, silicon oxide. Although the blocking insulating film 43 includes a single-layer film such as a silicon oxide film or the like in the example shown in FIG. 1, the blocking insulating film 43 may include multiple films. In the case where the blocking insulating film 43 includes multiple films, a stacked film of a silicon oxide film and a metal oxide film such as an aluminum oxide film or the like is used for the blocking insulating film 43. When forming the electrode layers 11, for example, the blocking insulating film 43 protects the charge storage film 42 from the etching. The blocking insulating film 43 prevents discharge of the charge stored in the charge storage film 42 into the electrode layer 11 and/or back-tunneling of electrons from the electrode layer 11 into the columnar part CL.

The columnar part CL includes a first columnar part CL1, a second columnar part CL2, and a linking portion C1. The first columnar part CL1, the second columnar part CL2, and the linking portion C1 are formed as one body inside the memory hole MH.

The first columnar part CL1 is a portion of the columnar part CL positioned inside the first stacked body 15a. The first columnar part CL1 includes the core insulating film 51, the channel 52, the tunneling insulating film 41, the charge storage film 42, and the blocking insulating film 43.

The second columnar part CL2 is a portion of the columnar part CL positioned inside the second stacked body 15b. The second columnar part CL2 includes the core insulating film 51, the channel 52, the tunneling insulating film 41, the charge storage film 42, and the blocking insulating film 43. For example, the thickness in the X-direction (the Y-direction) of the second columnar part CL2 is substantially the same as the thickness in the X-direction (the Y-direction) of the first columnar part CL1. The memory hole MH in which the first columnar part CL1 and the second columnar part CL2 are formed may have variation of hole diameter due to the manufacturing process; but, herein, the dimensions of the first columnar part CL1 and the second columnar part CL2 such as the thicknesses thereof are taken to be substantially equal to each other when the difference of the dimensions is about the variation caused in the manufacturing process. When viewed in the Z-direction, a portion of the second columnar part CL2 does not overlap the first columnar part CL1.

The linking portion C1 is a portion of the columnar part CL positioned inside the insulating layer 22a, the electrode layer 21, and the insulating layer 22b. The linking portion C1 is positioned between the first columnar part CL1 and the second columnar part CL2. The linking portion C1 includes the core insulating film 51, the channel 52, the tunneling insulating film 41, the charge storage film 42, and the blocking insulating film 43.

The linking portion C1 includes a support portion P1 and a bulge portion P2. The support portion P1 is positioned inside the insulating layer 22a. The support portion P1 has the thickness W1 in the Z-direction. The thickness W1 in the Z-direction of the support portion P1 is substantially the same as the thickness in the Z-direction of the insulating layer 22a. The thickness W1 is, for example, not less than 40 nanometers and not more than 110 nanometers.

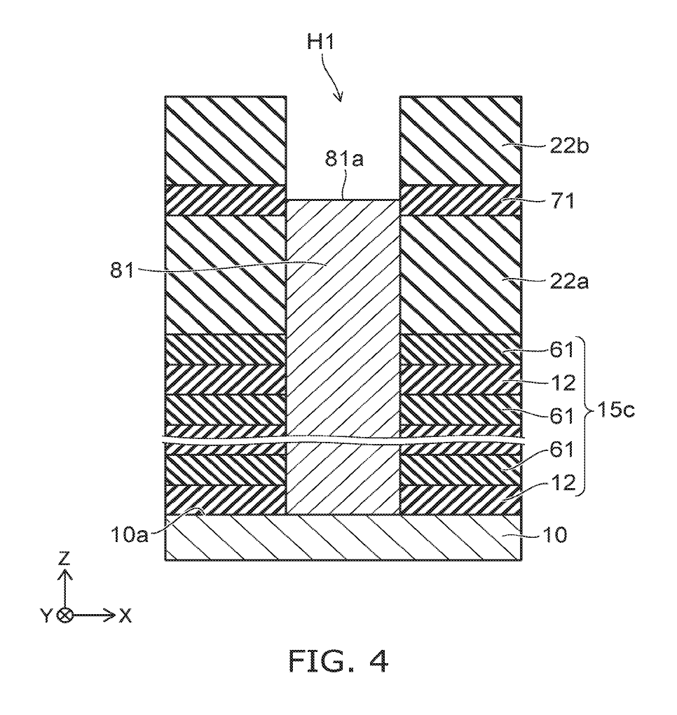

The bulge portion P2 is positioned inside the electrode layer 21 and the insulating layer 22b, and is a portion where the thickness in the X-direction (the Y-direction) is wider inside the linking portion C1. A portion of the bulge portion P2 is positioned between the upper surface and the lower surface of the electrode layer 21. In the example shown in FIG. 1, the thickness in the X-direction (the Y-direction) of the bulge portion P2 is wide compared to the support portion P1. For example, the thickness in the X-direction (the Y-direction) of the bulge portion P2 is not less than 1.05 times and not more than 1.15 times the thickness in the X-direction (the Y-direction) of the support portion P1. The bulge portion P2 has a thickness W2 in the Z-direction. The thickness W2 in the Z-direction of the bulge portion P2 is substantially the same as the sum of the thicknesses in the Z-direction of the electrode layer 21 and the insulating layer 22b. The thickness W2 is, for example, not less than 50 nanometers and not more than 110 nanometers. For example, the thickness W2 is about 70 nanometers considering the formation process of the bulge portion P2 (the processes of FIG. 4 to FIG. 6).

The thickness in the Z-direction of the linking portion C1 is the sum of the thickness W1 and the thickness W2. The thickness W1 corresponds to the distance in the Z-direction between the bulge portion P2 of the linking portion C1 and the electrode layer 11a of the uppermost layer of the first stacked body 15a.

An insufficient thickness portion f1 and a sufficient thickness portion s1 are provided in the linking portion C1 (the support portion P1). The insufficient thickness portion f1 is a portion that includes the memory film 55 and corresponds to a portion where the thickness of the memory film 55 is insufficient compared to the sufficient thickness portion s1. The insufficient thickness portion f1 is positioned inside the insulating layer 22a. The sufficient thickness portion s1 is a portion that includes the memory film 55 and corresponds to a portion other than the insufficient thickness portion f1. In the example shown in FIG. 1, the thickness in the X-direction of the insufficient thickness portion f1 is thinner than the thickness in the X-direction of the sufficient thickness portion s1.

In the semiconductor memory device 1, many memory cells that each include the charge storage film 42 are arranged in a three-dimensional lattice configuration along the X-direction, the Y-direction, and the Z-direction and are included in a memory cell array; and data can be stored in each of the memory cells.

A method for manufacturing the semiconductor memory device according to the embodiment will now be described.

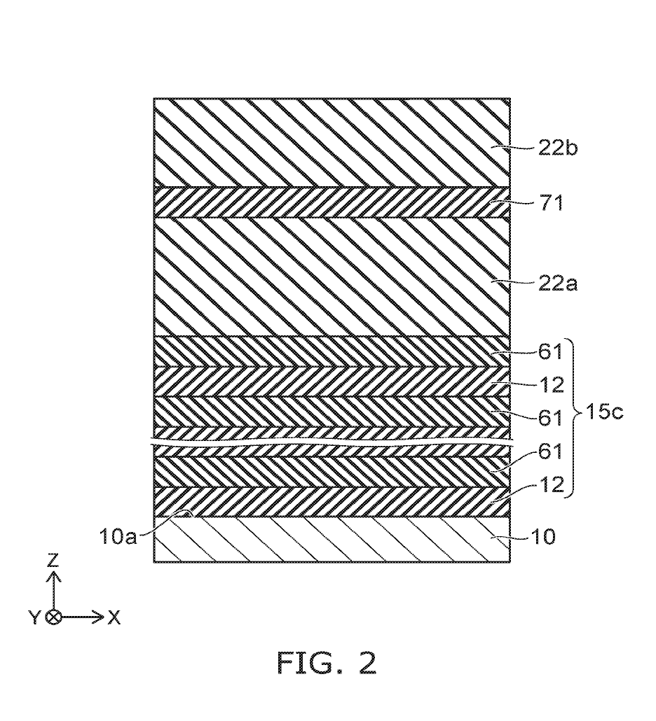

FIG. 2 to FIG. 13 are drawings showing the method for manufacturing the semiconductor memory device 1. The regions shown in FIG. 2 to FIG. 13 correspond to the region shown in FIG. 1.

First, as shown in FIG. 2, a stacked body 15c is formed on the substrate 10 by alternately stacking the insulating layers 12 and sacrificial layers 61 along the Z-direction by using, for example, CVD (Chemical Vapor Deposition). For example, the insulating layers 12 are formed of silicon oxide; and the sacrificial layers 61 are formed of silicon nitride.

Then, the insulating layer 22a is formed on the stacked body 15c using, for example, CVD; and a sacrificial layer 71 is formed on the insulating layer 22a. Subsequently, the insulating layer 22b is formed on the sacrificial layer 71. For example, the insulating layer 22a and the insulating layer 22b are formed of silicon oxide; and the sacrificial layer 71 is formed of the same material as the sacrificial layers 61, e.g., silicon nitride.

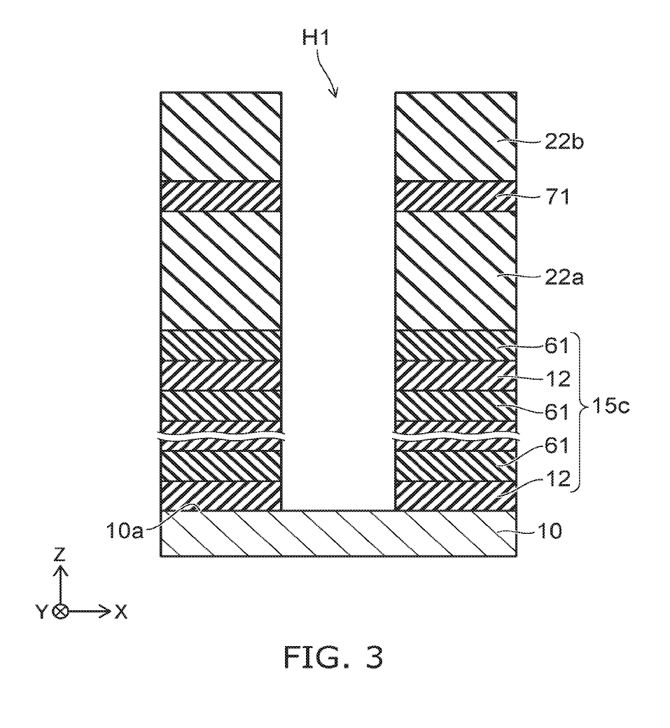

Then, a through-hole H1 is formed in the stacked body 15c, the insulating layer 22a, the sacrificial layer 71, and the insulating layer 22b as shown in FIG. 3. The through-hole H1 is formed through a photolithography process using a mask and an etching process using RIE (Reactive Ion Etching) or the like. The through-hole H1 extends through the insulating layer 22b, the sacrificial layer 71, the insulating layer 22a, and the stacked body 15c, and reaches the substrate 10. In the case where multiple through-holes H1 are formed, the multiple through-holes H1 are arranged, for example, in a lattice configuration when viewed in the Z-direction.

Then, as shown in FIG. 4, a sacrificial film 81 is formed inside the through-hole H1 by depositing amorphous silicon, etc. The sacrificial film 81 may be formed of polysilicon in which amorphous silicon is crystallized.

Subsequently, a portion of the sacrificial film 81 positioned at the upper portion of the through-hole H1 is removed inside the through-hole H1 through an etching process using such as RIE, etc. Etch-back of the sacrificial film 81 is performed so that an upper surface 81a of the sacrificial film 81 is positioned between the upper surface and the lower surface of the sacrificial layer 71.

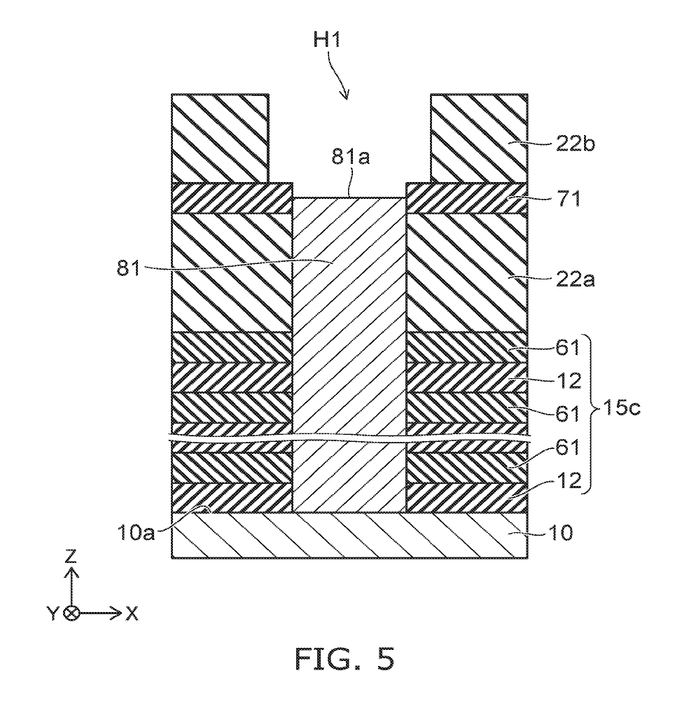

Then, a portion of the insulating layer 22b is removed by performing wet etching in the portion of the through-hole H1 where the portion of the sacrificial film 81 is removed as shown in FIG. 5. Thereby, a portion of the sacrificial layer 71 is exposed; and the width of the upper portion of the through-hole H1 widens in the X-direction and the Y-direction.

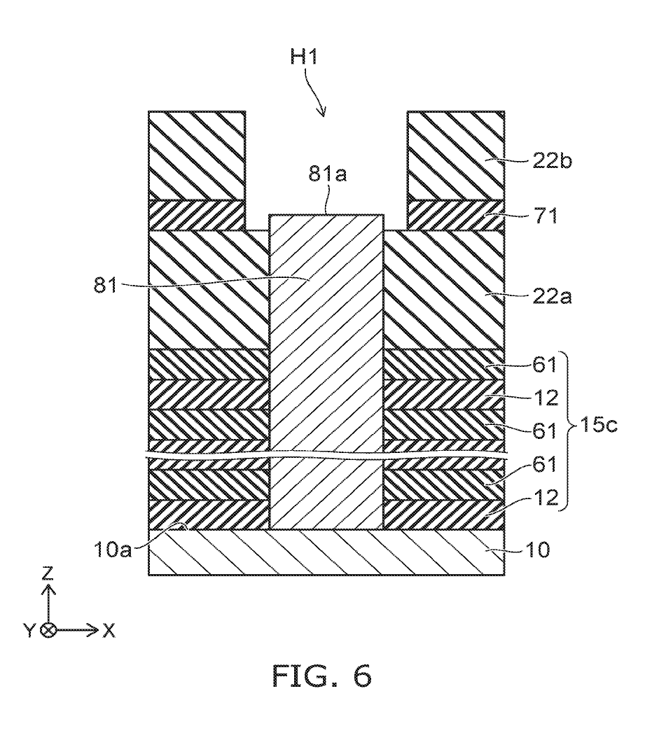

Then, as shown in FIG. 6, a portion of the exposed sacrificial layer 71 is removed through an etching process using such as RIE, etc. Thereby, the upper portion of the through-hole H1 widens in the X-direction, the Y-direction, and the Z-direction; and a portion of the insulating layer 22a and a portion of the sacrificial film 81 including the upper surface 81a are exposed.

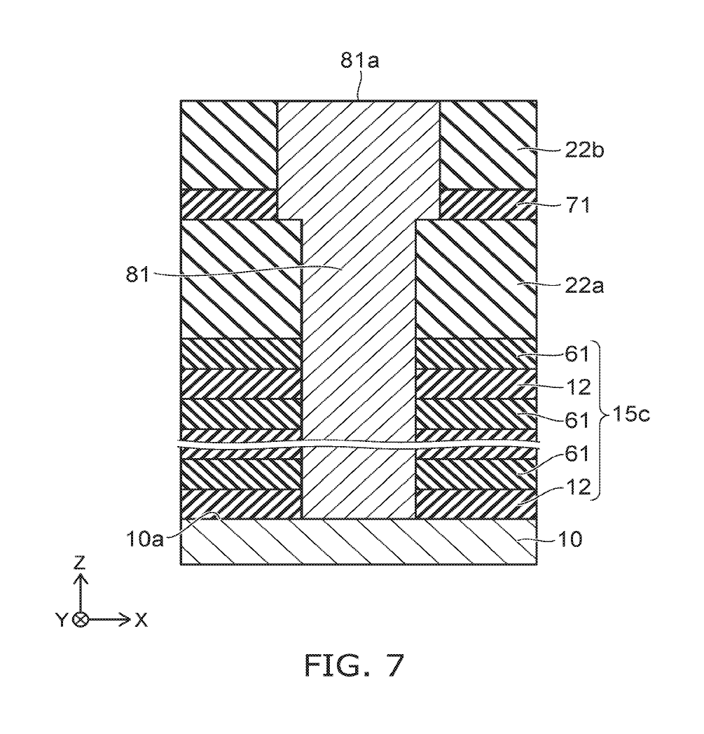

Then, as shown in FIG. 7, the sacrificial film 81 is re-formed by filling the interior of the through-hole H1 with amorphous silicon (or polysilicon); and subsequently, the sacrificial film 81 that is on the insulating layer 22b is removed by etching such as RIE, etc. Thereby, the upper surface 81a of the sacrificial film 81 is positioned in a plane substantially same as the upper surface of the insulating layer 22b.

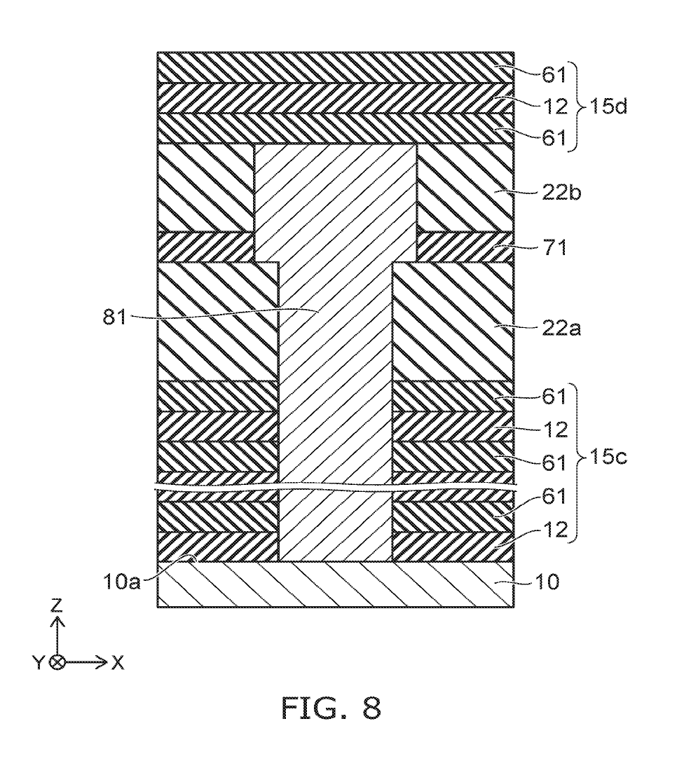

Then, as shown in FIG. 8, a stacked body 15d is formed on the insulating layer 22b and the sacrificial film 81 by alternately stacking the sacrificial layers 61 and the insulating layers 12 along the Z-direction by using, for example, CVD.

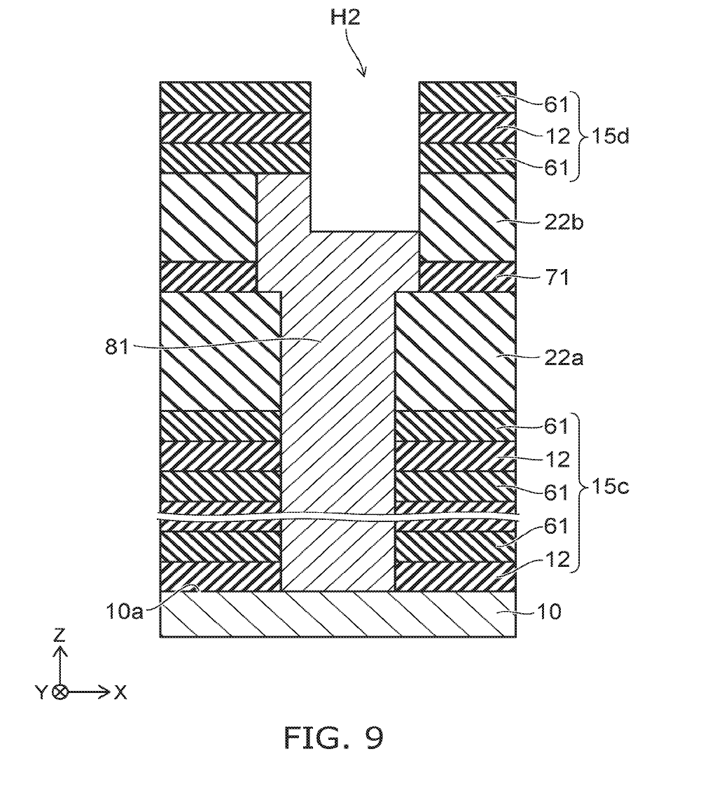

Then, as shown in FIG. 9, a through-hole H2 is formed in the stacked body 15d through a photolithography process using a mask and an etching process using such as RIE, etc. The through-hole H2 extends through the stacked body 15d, and reaches the sacrificial film 81. In the etching process, the insulating layers 12 and the sacrificial layers 61 of the stacked body 15d have selectivity with respect to the sacrificial film 81; and the sacrificial film 81 is used as an etching stopper; but a portion of the sacrificial film 81 may be removed by over-etching of the through-hole H2.

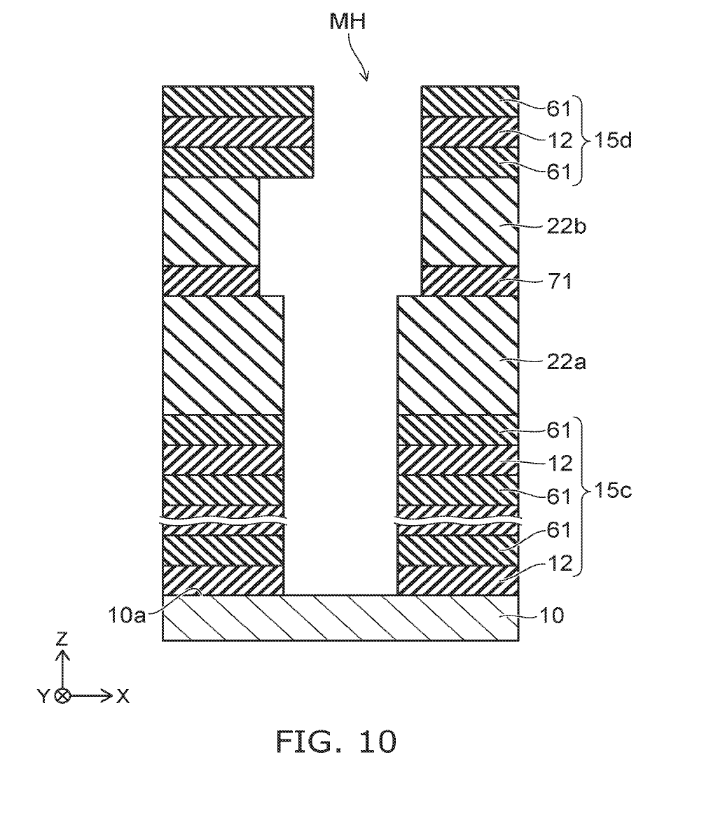

Then, as shown in FIG. 10, the sacrificial film 81 is selectively removed by performing wet etching in the through-hole H2. For example, a choline aqueous solution (TMY) is used as the etchant of the wet etching. Thereby, the memory hole MH is formed through the stacked body 15c, the insulating layer 22a, the sacrificial layer 71, the insulating layer 22b, and the stacked body 15d.

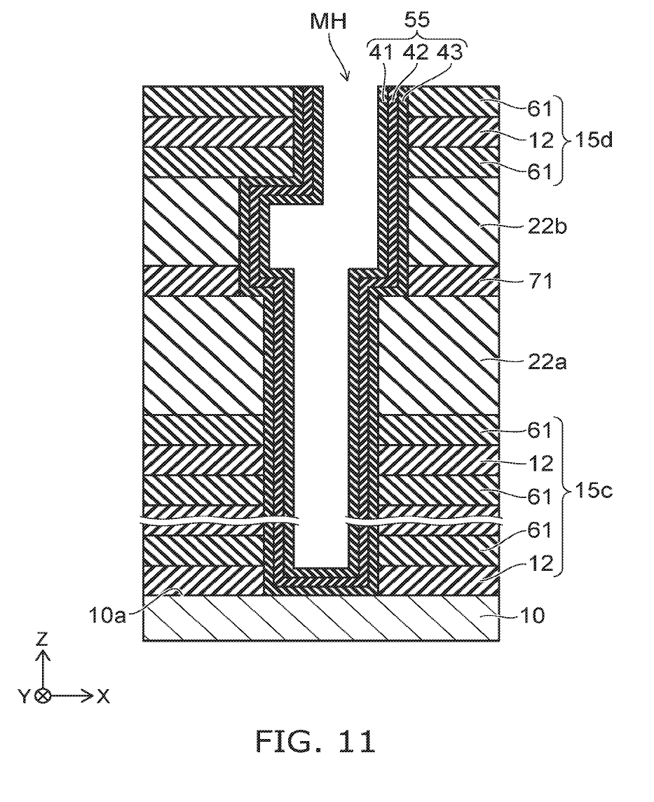

Then, as shown in FIG. 11, the blocking insulating film 43 is formed on the inner surface of the memory hole MH by depositing silicon oxide using, for example, CVD; and the charge storage film 42 is formed on the blocking insulating film 43 by depositing silicon nitride. Subsequently, the tunneling insulating film 41 is formed on the charge storage film 42 by depositing silicon oxide. Thereby, the memory film 55 is formed, which includes the tunneling insulating film 41, the charge storage film 42, and the blocking insulating film 43.

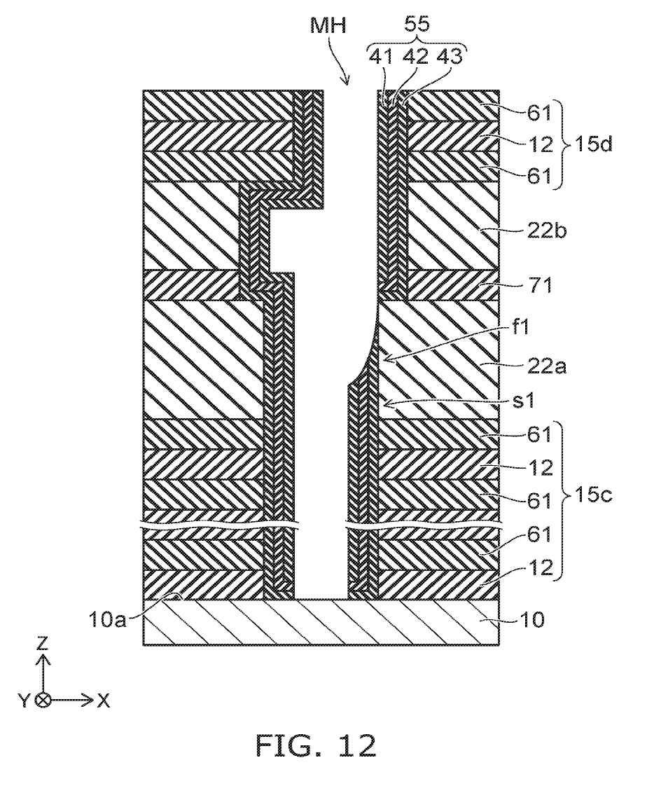

Then, as shown in FIG. 12, the tunneling insulating film 41, the charge storage film 42, and the blocking insulating film 43 are removed at the bottom surface of the memory hole MH, for example, by selective etching such as RIE and the like so that the upper surface 10a of the substrate 10 is exposed.

Here, in the case where, for example, the position of the through-hole H2 (formed in the process of FIG. 9) is shifted in the X-Y plane with respect to the position of the through-hole H1 (formed in the process of FIG. 3) in the X-Y plane, a portion of the memory film 55 surrounded by the insulating layer 22a is removed easily through the etching process for the memory film 55 at the bottom surface of the memory hole MH. Thereby, the insufficient thickness portion f1 is formed on the inner wall surface of the memory hole MH. The insufficient thickness portion f1 is positioned inside the insulating layer 22a, and corresponds to a portion where the thickness of the memory film 55 is less than the thickness of the sufficient thickness portion s1.

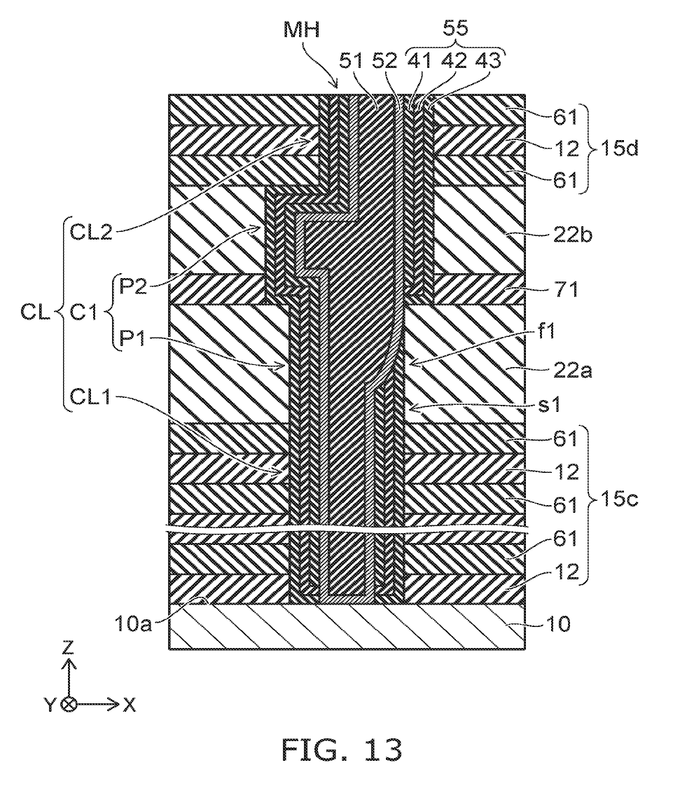

Then, as shown in FIG. 13, the channel 52 is formed by depositing silicon; and the core insulating film 51 is formed by depositing silicon oxide. Thereby, the columnar part CL that includes the first columnar part CL1, the second columnar part CL2, and the linking portion C1 is formed inside the memory hole MH. The first columnar part CL1, the second columnar part CL2, and the linking portion C1 each include the core insulating film 51, the channel 52, the tunneling insulating film 41, the charge storage film 42, and the blocking insulating film 43. Also, the linking portion C1 includes the support portion P1 and the bulge portion P2. Moreover, the channel 52 contacts the substrate 10.

Subsequently, multiple slits (not illustrated) are formed so as to extend in the Z-direction through the stacked body 15c the insulating layer 22a, the sacrificial layer 71, the insulating layer 22b, and the stacked body 15d.

Then, as shown in FIG. 1, the sacrificial layers 61 and 71 are removed by etching via the slits. For example, in the case where the sacrificial layers 61 and 71 are formed of silicon nitride, gaps are formed by removing the sacrificial layers 61 and 71 via the slits through wet etching using phosphoric acid as the etchant. Subsequently, the interiors of the gaps are filled by depositing a metal such as tungsten or the like via the slits, and the electrode layers 11 and 21 are formed in the gaps. Thereby, the sacrificial layers 61 of the stacked bodies 15c and 15d are replaced with the electrode layers 11; and the first stacked body 15a and the second stacked body 15b are formed, which respectively include the electrode layers 11 and the insulating layers 12. The first stacked body 15a corresponds to the lower stacked body; and the second stacked body 15b corresponds to the upper stacked body.

Subsequently, the contact and the bit line are formed on the columnar part CL so that the bit line is connected to the channel 52 via the contact. Thus, the semiconductor memory device 1 according to the embodiment is manufactured.

Then, the advantages of the embodiment will now be described.

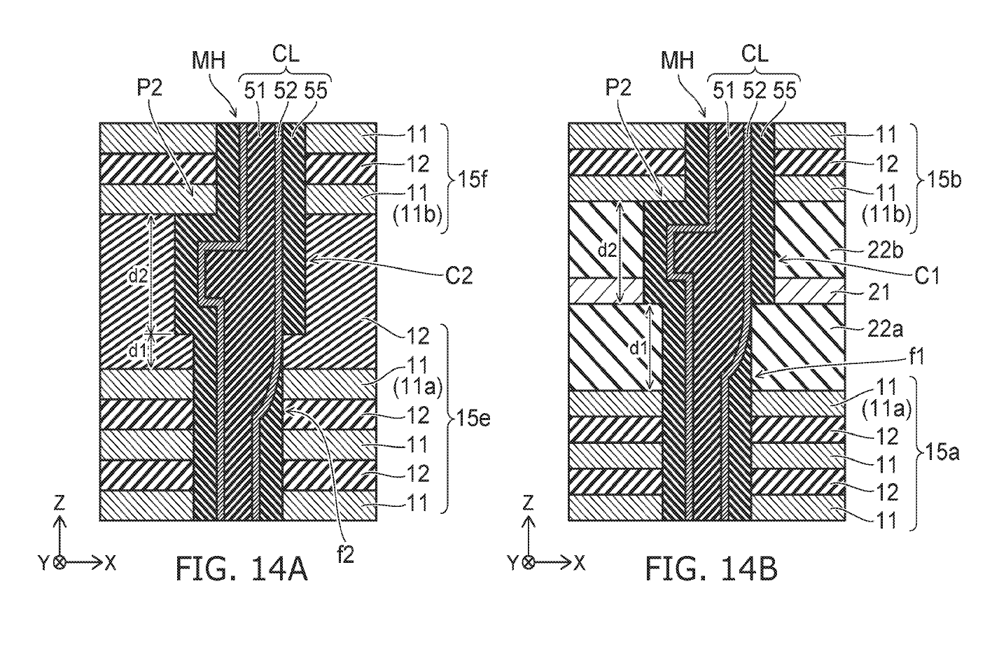

FIG. 14A is a cross-sectional view showing a portion of a semiconductor memory device according to a reference example.

FIG. 14B is a cross-sectional view showing a portion of the semiconductor memory device according to the first embodiment.

In FIG. 14A and FIG. 14B, the cross-sections are shown each corresponding to a portion of the cross-section shown in FIG. 1.

In a semiconductor memory device having a three-dimensional structure, the stacked body and the memory hole are formed in multi-steps when increasing the number of stacks of the stacked body. For example, as shown in FIG. 14A, an upper stacked body 15f is provided on a lower stacked body 15e; and the columnar part CL extends in the Z-direction inside the memory hole MH formed through the stacked body 15e and the stacked body 15f. The columnar part CL includes the core insulating film 51, the channel 52, and the memory film 55. The core insulating film 51, the channel 52, and the memory film 55 are formed inside the stacked body 15e and the stacked body 15f through a linking portion C2 of the columnar part CL. The linking portion C2 is positioned inside the insulating layer 12 that is the uppermost layer of the stacked body 15e.

When forming the memory hole MH, for example, there are cases where an insufficient thickness portion f2 is formed on the inner wall surface of the memory hole MH due to the positional shift in the X-Y plane of the through-hole inside the stacked body 15f with respect to the through-hole in the stacked body 15e. The insufficient thickness portion f2 is positioned inside the stacked body 15e and/or the linking portion C2, which corresponds to a portion where the thickness of the memory film 55 is insufficient compared to the other portions. Due to the insufficient thickness portion f2, a leakage current between the electrode layers 11 of the stacked body 15e and the channel 52 of the columnar part CL occurs easily in the operation of the memory cells.

Here, it may be considered to suppress the leakage current generated at the insufficient thickness portion f2 by widening a distance d1 in the Z-direction between the bulge portion P2 of the linking portion C2 and the electrode layer 11a that is the uppermost layer of the multiple electrode layers 11 of the stacked body 15e. However, when the distance d1 is widened, the distance in the Z-direction is widened between the electrode layer 11a and the electrode layer 11b that is the lowermost layer of the multiple electrode layers 11 of the stacked body 15f. In contrast, it is desirable to ensure a distance d2, which corresponds to the thickness in the Z-direction of the bulge portion P2, to be sufficient to perform the formation process of the bulge portion P2 using an etching or the like.

Accordingly, the total thickness of the linking portion C2 corresponding to the sum of the distance d1 and the distance d2 is widened by widening the distance d1. Thereby, the distance between the electrode layer 11a and the electrode layer 11b lengthens; and the cell current amount tends to decrease in the operation of the memory cells. Thus, the degradation of operating characteristics easily occurs in the memory cell.

In the semiconductor memory device 1 according to the embodiment, the linking portion C1 is provided in the columnar part CL such that the bulge portion P2 has the wide thickness in the X-direction (and the Y-direction). Moreover, the electrode layer 21 is positioned between the upper surface and the lower surface of the bulge portion P2 in the Z-direction. Providing the linking portion C1 and the electrode layer 21 makes it possible to suppress the decrease of the cell current amount in the operation of the memory cells while suppressing the occurrence of the leakage current.

For example, as shown in FIG. 14B, when ensuring a large distance d1 in the Z-direction between the bulge portion P2 of the linking portion C1 and the electrode layer 11a of the uppermost layer of the multiple electrode layers 11 of the first stacked body 15a, the leakage current is suppressed because the insufficient thickness portion f1 is provided at a position distal to the electrode layer 11a of the uppermost layer of the first stacked body 15a.

Also, by widening the distance d1, even in the case where the thickness of the linking portion C1 (the sum of the distance d1 and the distance d2) widens, the decrease of the cell current amount is suppressed in the operation of the memory cells because the electrode layer 21 is positioned between the first stacked body 15a and the second stacked body 15b. Accordingly, the degradation of the operating characteristics of the memory cells is suppressed. The bulge portion P2 is formed easily in the formation process of the bulge portion P2 because a constant distance can be ensured without changing the distance d2 corresponding to the thickness in the Z-direction of the bulge portion P2.

According to the embodiment, a semiconductor memory device and a method for manufacturing the semiconductor memory device are provided in which the operating characteristics of the memory cells are improved.

A modification of the embodiment will now be described.

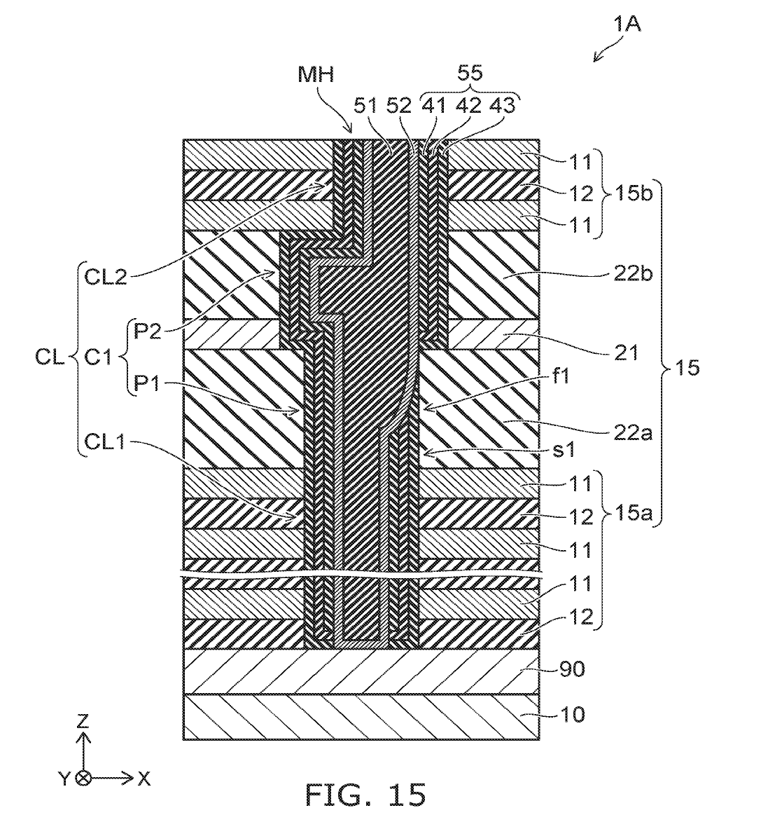

FIG. 15 is a cross-sectional view showing a semiconductor memory device 1A according to the modification of the first embodiment.

In the modification, a foundation layer 90 is provided between the substrate 10 and the first stacked body 15a. Otherwise, the configuration is the same as the embodiment; and a detailed description is therefore omitted.

As shown in FIG. 15, the foundation layer 90 is provided in the semiconductor memory device 1A. The foundation layer 90 includes, in the upper surface side of the foundation layer 90, an interconnect layer that is used as the source of the memory cell array and is connected to the channel 52; and under the interconnect layer, the foundation layer 90 includes not-illustrated circuit elements, interconnects, etc., as an under-cell circuit. That is, as in the modification, the foundation of the first stacked body 15a is not limited to the substrate 10; and the foundation layer 90 in which circuit elements, interconnects, etc., are formed on the substrate 10 may be formed as the foundation.

### Second Embodiment

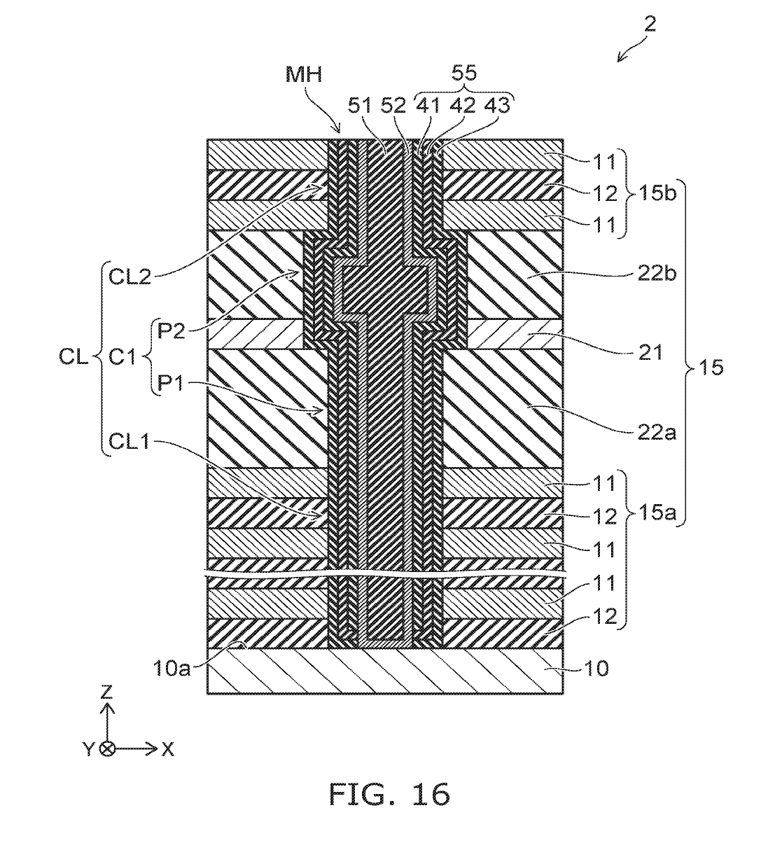

FIG. 16 is a cross-sectional view showing a semiconductor memory device 2.

The configuration of the linking portion C1 of the semiconductor memory device 2 according to the embodiment is different from that of the semiconductor memory device 1 of the first embodiment. Otherwise, the configuration is the same as the first embodiment; and a detailed description is therefore omitted.

As shown in FIG. 16, the columnar part CL is configured as one body inside the memory hole MH from the first columnar part CL1, the second columnar part CL2, and the linking portion C1.

For example, similarly to the first embodiment, the thickness in the X-direction (the Y-direction) of the second columnar part CL2 is substantially the same as the thickness in the X-direction (the Y-direction) of the first columnar part CL1. On the other hand, the second columnar part CL2 substantially overlaps the first columnar part CL1 when viewed from the Z-direction. The first columnar part CL1 and the second columnar part CL2 extend in the Z-direction with the linking portion C1 including the support portion P1 and the bulge portion P2 interposed. In the case where the second columnar part CL2 substantially overlaps the first columnar part CL1 in the Z-direction, the insufficient thickness portion f1 is not formed in the support portion P1. Thus, the columnar part CL may be formed by the first columnar part CL1, the second columnar part CL2, and the linking portion C1 having positional relationships and configurations such as that shown in FIG. 16.

The advantages of the second embodiment are the same as the effects of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device, comprising:
a substrate;
a stacked body provided above the substrate, the stacked body including a plurality of electrode layers stacked to be separated from each other, the plurality of electrode layers being stacked in a first direction; and
a columnar part being provided inside the stacked body, the columnar part including a semiconductor part and a memory film, the semiconductor part extending in the first direction, the memory film being provided between the stacked body and the semiconductor part,
the plurality of electrode layers including a plurality of first electrode layers, a plurality of second electrode layers, and a third electrode layer provided between the plurality of first electrode layers and the plurality of second electrode layers,
the stacked body including a first stacked body and a second stacked body, the first stacked body including the plurality of first electrode layers and being positioned on the substrate side, the second stacked body including the plurality of second electrode layers, the third electrode layer being positioned between the first stacked body and the second stacked body,
the columnar part including a first columnar part, a second columnar part, and a linking portion, the first columnar part being provided inside the first stacked body, the second columnar part being provided inside the second stacked body, the linking portion being provided between the first columnar part and the second columnar part,
the linking portion including a first portion, the first portion having a first thickness in a second direction crossing the first direction, the first thickness being wider than a thickness in the second direction of other portion in the linking portion, the first portion including a portion positioned in the first direction between an upper surface and a lower surface of the third electrode layer.

2. The device according to claim 1, wherein the third electrode layer is a dummy electrode layer.

3. The device according to claim 1, wherein the first thickness of the first portion of the linking portion is larger than a thickness in the second direction of the first columnar part and a thickness in the second direction of the second columnar part.

4. The device according to claim 1, further comprising:
a first intermediate insulating layer facing the lower surface of the third electrode layer, the first intermediate insulating layer being provided between the first stacked body and the third electrode layer; and
a second intermediate insulating layer facing the upper surface of the third electrode layer, the second intermediate insulating layer being provided between the second stacked body and the third electrode layer,
the stacked body further including a first inter-layer insulating layer and a second inter-layer insulating layer, the first inter-layer insulating layer being positioned between the plurality of first electrode layers inside the first stacked body, the second inter-layer insulating layer being positioned between the plurality of second electrode layers inside the second stacked body,
the first intermediate insulating layer and the second intermediate insulating layer each having a thickness in the first direction thicker than a thickness in the first direction of the first inter-layer insulating layer,
the first intermediate insulating layer and the second intermediate insulating layer each having the thickness in the first direction thicker than a thickness in the first direction of the second inter-layer insulating layer,
the linking portion further including a second portion provided between the first columnar part and the first portion.

5. The device according to claim 4, wherein
the memory film includes a thin film portion, and at a boundary between the first portion and the second portion of the linking portion, the thin film portion has a thickness in the second direction thinner than a thickness in the second direction of other portion of the memory film.

6. The device according to claim 5, wherein the thin film portion has a thickness in the second direction becoming thicker in a direction from the boundary toward the plurality of first electrode layers.

7. The device according to claim 4, wherein
the second portion of the linking portion has a thickness in the second direction thinner than the first thickness of the first portion of the linking portion, and
the thickness in the second direction of the second portion is substantially same as a thickness in the second direction of the first columnar part.

8. The device according to claim 1, wherein
the semiconductor part is provided such that a width in the second direction of an outer perimeter at the first portion is wider than a width in the second direction of the outer perimeter at the first columnar part, and the width in the second direction of the outer perimeter at the first portion is wider than a width in the second direction of the outer perimeter at the second columnar part.

9. The device according to claim 1, wherein the columnar part further includes an insulating body extending in the first direction, the insulating body being positioned on an inner side of the semiconductor part.

10. The device according to claim 9, wherein
the insulating body is provided such that a width in the second direction of an outer perimeter at the first portion is wider than a width in the second direction of the outer perimeter at the first columnar part, and the width in the second direction of the outer perimeter at the first portion is wider than a width in the second direction of the outer perimeter at the second columnar part.

11. A semiconductor memory device, comprising:
a substrate;
a stacked body provided above the substrate, the stacked body including a first stacked body, a first intermediate insulating layer, an intermediate electrode layer, a second intermediate insulating layer, and a second stacked body, the first stacked body including a plurality of first electrode layers stacked in a first direction, the plurality of first electrode layers being separated from each other, the first intermediate insulating layer being provided on the first stacked body, the intermediate electrode layer being provided on the first intermediate insulating layer, the second intermediate insulating layer being provided on the intermediate electrode layer, the second stacked body being provided on the second intermediate insulating layer, the second stacked body including a plurality of second electrode layers stacked in the first direction, the plurality of second electrode layers being separated from each other; and
a columnar part provided inside the stacked body, the columnar part including a semiconductor part and a memory film, the semiconductor part extending in the first direction, the memory film being provided between the stacked body and the semiconductor part,
the columnar part including a first portion, a second portion, and a bulge portion, the first portion being positioned at least inside the first stacked body, the second portion being positioned at least inside the second stacked body, the first portion having a first thickness in a second direction crossing the first direction, the first thickness being substantially equal to a second thickness in a second direction of the second portion, the bulge portion being provided between the first portion and the second portion, the bulge portion having a thickness in the second direction thicker than the first thickness and the second thickness,
the bulge portion being provided in the first direction at least from a lower surface of the intermediate electrode layer to an upper surface of the second intermediate insulating layer.

12. The device according to claim 11, wherein the intermediate electrode layer is a dummy electrode layer.

13. The device according to claim 11, wherein
an uppermost first electrode layer among the plurality of first electrode layers is a dummy electrode layer, and
a lowermost second electrode layer among the plurality of second electrode layers is a dummy electrode layer.

14. The device according to claim 11, wherein
the first stacked body further includes a first inter-layer insulating layer positioned between the plurality of first electrode layers,
the second stacked body further includes a second inter-layer insulating layer positioned between the plurality of second electrode layers,
the first intermediate insulating layer and the second intermediate insulating layer have thicknesses in the first direction thicker than a thickness in the first direction of the first inter-layer insulating layer, and
the first intermediate insulating layer and the second intermediate insulating layer have thicknesses in the first direction thicker than a thickness in the first direction of the second inter-layer insulating layer.

15. The device according to claim 11, wherein the memory film includes a portion provided at a position where the first portion of the columnar part is linked to the bulge portion of the columnar part, the portion of the memory film having a thickness in the second direction thinner than a thickness in the second direction of other portion of the memory film.

16. The device according to claim 11, wherein the memory film includes a portion inside the first intermediate insulating layer, the portion of the memory film having a thickness in the second direction becoming thicker in a direction from the intermediate electrode layer toward an uppermost first electrode layer of the plurality of first electrode layers.

17. The device according to claim 11, wherein the memory film includes a first film provided between the stacked body and the semiconductor part, a charge storage film provided between the first film and the semiconductor part, and a second film provided between the charge storage film and the semiconductor part.

18. The device according to claim 11, wherein the second portion of the columnar part is provided at a position such that a center of the second portion is shifted from a center of the first portion of the columnar part when viewed in the first direction.

19. A method for manufacturing a semiconductor memory device, comprising:
forming a first stacked body on a foundation by alternately stacking a first insulating layer and a first layer;
forming a second insulating layer on the first stacked body;
forming a second layer on the second insulating layer;
forming a third insulating layer on the second layer;
forming a first through-hole extending in a first direction in the first stacked body, the second insulating layer, the second layer, and the third insulating layer;
forming a first film inside the first through-hole;
removing a portion of the first film from an upper portion of the first through-hole;
removing a portion of the third insulating layer to expose a portion of the second layer, the portion of the third insulating layer being removed from a portion of the first through-hole, in which the portion of the first film is removed, toward a second direction and a third direction crossing each other and being orthogonal to the first direction;
removing an exposed portion of the second layer to expose a portion of the second insulating layer;
forming a second film inside an upper portion of the first through-hole including the portion in which the third insulating layer is removed after the removing of the exposed portion of the second layer;
forming a second stacked body on the third insulating layer and the second film by alternately stacking a third layer and a fourth insulating layer;
forming a second through-hole extending in the first direction in the second stacked body, the second through-hole reaching the second film;
removing the first film and the second film inside the first through-hole through the second through-hole;
forming a memory film on an inner wall surface of the first through-hole and on an inner wall surface of the second through-hole;
forming a semiconductor part on the memory film inside the first through-hole and the second through-hole;
forming a slit extending in the first direction in the first stacked body, the second insulating layer, the second layer, the third insulating layer, and the second stacked body;
removing the first layer of the first stacked body, the second layer, and the third layer of the second stacked body via the slit; and
forming electrode layers inside gaps formed by the removing of the first layer, the second layer, and the third layer.

20. The method according to claim 19, further comprising removing the memory film positioned on a bottom surface of the first through-hole to expose a portion of the foundation.
